(19) United States
(12) Patent Application Publication
(10) Pub. No.: US 2024/0230721 A1
(43) Pub. Date: Jul. 11, 2024

(54) SEMICONDUCTOR-BASED SENSE RESISTOR

(71) Applicant: Texas Instruments Incorporated, Dallas, TX (US)

(72) Inventors: Rushil Kishore Kumar, Bangalore (IN); James Robert Todd, Plano, TX (US); Jasjot Singh Chadha, Allen, TX (US); Anand Kannan, Bangalore (IN); Naresh Lagadapati, Bangalore (IN); Rejin K. Raveendranath, Bangalore (IN)

(21) Appl. No.: 18/404,873

(22) Filed: Jan. 4, 2024

Related U.S. Application Data
(60) Provisional application No. 63/437,262, filed on Jan. 5, 2023.

(51) Int. Cl. G01R 15/14; G01R 19/00

(52) U.S. Cl. CPC G01R 15/146; G01R 19/0046

(57) ABSTRACT

A semiconductor device includes a resistor head, a resistor body, and a sense terminal. The resistor head is constructed using a first material. The resistor body is coupled to the resistor head and is constructed using a second material having a higher resistivity than the first material. The sense terminal has a first section and a second section and is decoupled from the resistor head, in which the second section of the sense terminal is coupled between the first section of the sense terminal and the resistor body, with an end portion of the second section of the sense terminal coupled to the resistor body.

### CROSS-REFERENCE TO RELATED APPLICATION

This patent claims the benefit of U.S. Provisional Patent Application No. 63/437,262, which was filed on Jan. 5, 2023. U.S. Provisional Patent Application No. 63/437,262 is hereby incorporated herein by reference in its entirety. Priority to U.S. Provisional Patent Application No. 63/437,262 is hereby claimed.

### TECHNICAL FIELD

This disclosure relates generally to measuring electrical characteristics in temperature dynamic environments and, more particularly, to a semiconductor-based sense resistor that may be used for current measurements.

### BACKGROUND

Electrical characteristic measurements enable electronic devices to perform tasks in a manner consistent with design specifications. Resistors are a particular example of an electronic component used in electronic devices that enable current data to be determined based on measured voltage values over the resistor.

### SUMMARY

In a first example, a semiconductor device includes a resistor head, a resistor body, and a sense terminal. The resistor head is constructed using a first material. The resistor body is coupled to the resistor head and is constructed using a second material having a higher resistivity than the first material. The sense terminal has a first section and a second section and is decoupled from the resistor head, in which the second section of the sense terminal is coupled between the first section of the sense terminal and the resistor body, with an end portion of the second section of the sense terminal coupled to the resistor body.

In another example, a semiconductor device includes a resistor head, a resistor body, and a sense terminal. The resistor head is constructed using a first material. The resistor body is coupled to the resistor head and is constructed using a second material having a higher resistivity than the first material. The sense terminal has a first section and a second section, in which the second section of the sense terminal is coupled between the first section of the sense terminal and the resistor body, with an end portion of the second section of the sense terminal coupled to the resistor body, and in which the end portion of the second section of the sense terminal is constructed using a third material having a higher resistivity the first material.

In another example, an integrated circuit includes a resistor, which includes a first resistor head, a resistor body, a second resistor head, and a sense terminal. The first resistor head is constructed using a first material. The resistor body is coupled to the first resistor head at a first side of the resistor body, and the resistor body is constructed using a second material having a higher resistivity than the first material. The second resistor head is coupled to a second side of the resistor body. The sense terminal has a first section and a second section and is decoupled from the resistor head, in which the second section of the sense terminal is coupled between the first section of the sense terminal and the resistor body, with an end portion of the second section of the sense terminal coupled to the resistor body. The first section of the sense terminal is constructed using a third material, and at least the end portion of the second section of the sense terminal is constructed using the second material.

### BRIEF DESCRIPTION OF THE DRAWINGS

FIG. 1 illustrates an example system including an example sense resistor, which may be used to sense an electrical characteristic of the system.

FIG. 2 illustrates an example sense resistor that may be used in the system of FIG. 1.

FIG. 3 illustrates a detailed portion of the example sense resistor of FIG. 2.

FIG. 4 illustrates an example sense resistor having example mask alignment and fabrication tolerance structures.

FIG. 5 illustrates an example sense resistor with sense terminals coupled in an alternative location.

FIG. 6 illustrates an example sense resistor with an alternative body structure.

FIG. 7 illustrates an example cross-sectional view of the sense resistor shown in FIG. 2.

FIG. 8A is a flowchart of an example manner of fabricating an example sense resistor, including the sense resistors (or portions thereof) shown in FIGS. 1-7.

FIGS. 8B through 8H illustrate example cross-sectional views of the sense resistor of FIGS. 2 and 7 in view of the example manner of fabrication of FIG. 8A.

FIG. 9 is an example graph illustrating temperature versus percent change in value corresponding to an example sense resistor.

In general, the same reference numbers are used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Accurate characteristic measurements, such as current measurements, in some electronic devices facilitate correspondingly accurate performance of those electronic devices. In some examples, accurate current measurements may be used to improve device safety and/or reduce damage to devices in the event over-current and/or over-temperature conditions. In some examples, amplifiers, such as a class-D amplifier, are a type of electronic device that operates over a relatively wide range of signal powers. A class-D amplifier may operate with any range of input power values, such as values between 3 mW and 7 W. At such relatively high power values, heat dissipation may affect surrounding components of the amplifier, such as a sense resistor. In this context, a sense resistor is taken to mean a resistor that is used to sense or measure a characteristic of or in a circuit such as a voltage and/or a current.

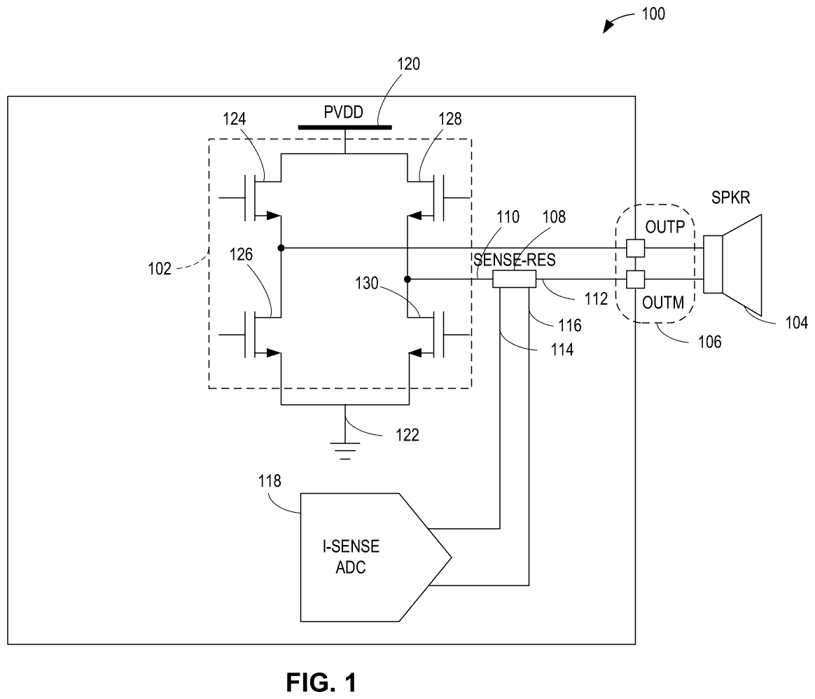

FIG. 1 illustrates an example system 100 within which one or more sense resistors consistent with this description may be implemented. As shown system 100 includes an example integrated circuit (IC) 140 coupled to an example audio device 104, which in this example is a speaker 104. The IC 140 may include a class-D amplifier, which represents a type of electronic device that may use and/or otherwise benefit from examples described herein. However, other electronic devices that use a sense resistor, for instance a sense resistor constructed with materials having different temperature coefficients, may benefit from the described examples.

In the example of FIG. 1, the IC 140 contains amplifier circuitry, which includes an output stage 102 for an amplifier (not shown—such as a class-D amplifier), a sense resistor 108 coupled to a terminal of the output stage 102, and sense circuitry 118 that may be used to sense a characteristic of the amplifier circuitry using the sense resistor 108. In some examples, the amplifier circuitry of the IC 140 includes additional components (not shown) such as, but not limited to: power management circuitry; integrated Boost circuitry for higher power delivery in battery-operated systems; various interfaces to external devices; clocking circuitry; a digital logic controller used to run speaker protection algorithms to enable high output SPL while keeping speakers in a safe operating region; a battery tracking peak voltage limiter and a battery voltage monitor ADC that enables advanced battery monitoring algorithms on the host processor to manage peak output power delivery while avoiding any audio distortion when battery capacity is depleting. Also, the IC 140 may be optimized for delivering the best battery life for real use cases of Music playback and Voice calls. For example, advanced efficiency optimization features like Class-H, Y-bridge, and algorithms enable the device to produce efficiency across all power regions of operation.

As shown, the output stage 102 includes field effect transistors (FETs) 124, 126, 128, and 130 coupled in an H-bridge configuration between a voltage supply terminal 120 and a ground terminal 122. The output stage 102 may be implemented using transistor types other than those shown, The output stage 102 is coupled to the speaker 104 via pads 106 of the IC 140. The sense resistor 108 includes an input current carrying terminal 110, an output current carrying terminal 112, a first sense terminal 114, and a second sense terminal 116. The first sense terminal 114 and the second sense terminal 116, also referred to as Kelvin-sense terminals, are coupled to the sense circuitry 118. In this example, the sense circuitry 118 is implemented as a current sense analog-to-digital converter (ADC) 118. The current sense ADC 118 facilitates real-time monitoring of a voltage across the sense resistor 108 to measure a current through the terminals 110 and 112 and into the speaker 104. In some examples, the current sense ADC 118 collects data to facilitate speaker protection algorithms, which require accurate current value data to enable safe operating control of the speakers.

In another example, the output stage 102 has a different structure, such as a half-bridge structure. In another example, the sense circuitry 118 has a different implementation. In another example, a pair of sense resistors (for instance according to the described examples) are included as part of the amplifier along with the output stage 102. For example, a first sense resistor is coupled between the source transistor 126 and the ground terminal 122, and a second sense resistor is coupled between the source of transistor 130 and the ground terminal 122.

In some examples, current sensing is performed using the sense resistor 108, in which the sense resistor 108 has a relatively low resistance value in an effort to improve a power efficiency when determining current values. In particular, a current value may be derived from a voltage measurement across the sense resistor 108 using Ohm's law. Additional efforts to determine a current value in a manner that considers power efficiency conservation include locating the sense resistor as close to a power-stage of the amplifier as possible, thereby reducing routing resistances. Of course, when the sense resistor 108 is close to the power-stage(s), the sense resistor experiences a corresponding temperature influence and/or fluctuation. In some examples, the sense resistor is selected to have a relatively low temperature coefficient in an effort to reduce measurement inaccuracy when temperatures fluctuate.

In some examples, the sense resistor 108 is a polycrystalline silicon resistor (sometimes referred to herein as a polysilicon resistor or a poly resistor) that exhibits a relatively low temperature coefficient and has a resistive body material coupled to a head material which includes metallic contacts which electrically connect to metal interconnects (e.g., terminals 110 and 112). While the resistive body material of the poly resistor has a relatively low temperature coefficient, the head material and the metal routing (e.g., metallic contacts and interconnects) have relatively high temperature coefficients. Accordingly, measuring a voltage drop across the primary current carrying terminals 110 and 112 of sense resistor 108 may result in a value that is substantially influenced by several layers or materials of the sense resistor 108, which include the metal routing on a first side, an adjacent head material, the resistive body material adjacent to another head material of a second side, and finally the metal routing of the second side.

Furthermore, when such sense resistors are influenced by temperature variations, voltage drop values may exhibit erroneous variations due to the several layers and their corresponding temperature coefficients. Accordingly, the sense resistor 108 described herein employs the first sense terminal 114 and the second sense terminal 116 to measure a voltage drop across the sense resistor 108 in a manner that is less influenced by temperature variations. As described in further detail below, the sense resistor 108 of FIG. 1 exhibits a sense terminal geometry to mitigate current bending effects that may cause errors when measuring a voltage drop over a body portion of the sense resistor 108.

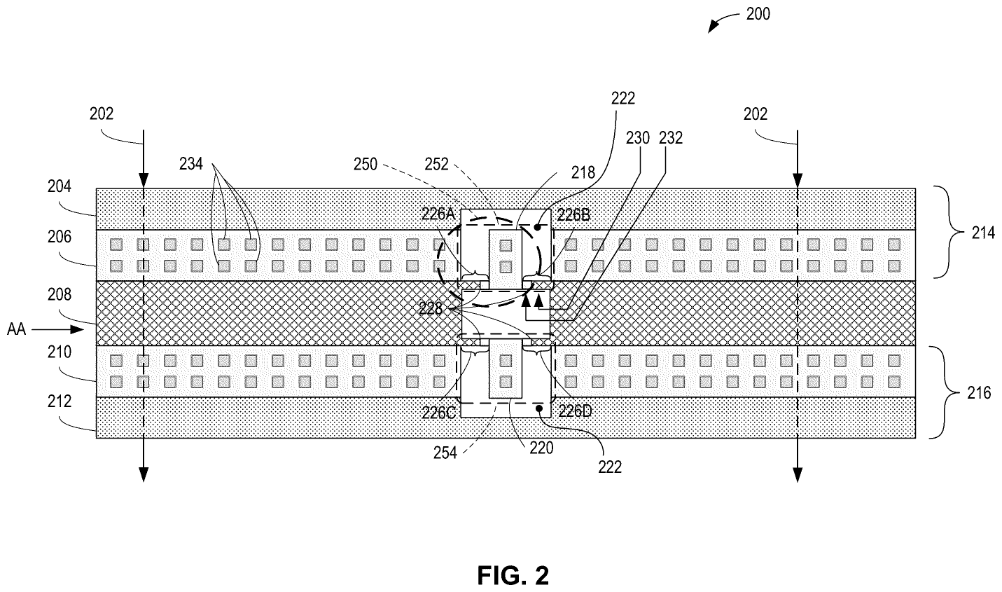

FIG. 2 is an example sense resistor 200 that may be implemented as the sense resistor 108. In the example of FIG. 2, a top-down view of the sense resistor is shown. The sense resistor 200 includes five (5) portions or segments (also referred to as layers) of material through which a current flows (see current flow arrows 202). The example of FIG. 2 includes a first metal interconnect 204 (sometimes referred to as a first metal layer) adjacent to a first resistive head 206 (sometimes referred to as a resistor head or a first head layer), which is adjacent to a resistive body 208 (sometimes referred to as a resistor body or a body layer).

The first metal interconnect 204 and the first resistive head 206 reflect a first side 214 of the sense resistor 200. Also, the example sense resistor 200 includes the resistive body 208 adjacent to a second resistive head 210 (sometimes referred to as a second resistor head or a second head layer) that is adjacent to a second metal interconnect 212 (sometimes referred to as a second metal layer) to reflect a second side 216 of the sense resistor 200. In some examples, the first metal interconnect 204 and/or the second metal interconnect 212 serve as terminals to conduct current through the sense resistor 200, and in some examples a surface of the first metal interconnect 204 and/or the second metal interconnect 212 serve as terminals that are conductively connected to a circuit (e.g., surface mount). In some examples, the first metal interconnect 204 is connected to or serves as the input current carrying terminal 110 of FIG. 1, and the second metal interconnect 212 is connected to or serves as the output current carrying terminal 112 of FIG. 1. In the example of FIG. 2, the first resistive head 206 and the second resistive head 210 include any number of resistor head contacts 234 (which may be referred to as metallic contacts), not all of which are numbered to simplify FIG. 2.

In the example of FIG. 2, the sense resistor 200 also includes a first sense terminal 252 on the first side of the sense resistor 200 and a second sense terminal 254 on the second side 216 of the sense resistor 200. Sense terminal 252 includes a first section 218 (also referred to herein as a conductive structure 218) and second sections 226A and 226B (each also referred to herein as a sense channel. The second sections 226A and 226B are coupled between the first section 218 and the body 208. Sense terminal 254 includes a first section 220 (also referred to herein as a conductive structure 220) and second sections 226C and 226D (each also referred to herein as a sense channel). The second sections 226C and 226D are coupled between the first section 220 and the body 208. These couplings help to facilitate more accurate voltage (and current) sensing at the terminals 252 and 254, for example across temperature variation. Respective sense channels 226 include a first portion of the sense channel 230 (sometimes referred to as a first section of the sense channel) having a first material and a second portion of the sense channel 232 (sometimes referred to as a second section of the sense channel) having a second material, in which the sense channel portions meet to form a sense interface 228. While the example of FIG. 2 illustrates the first portion of the sense channel 230 and the second portion of the sense channel 232 corresponding to the second sense channel 226B, similar structures may be present on remaining sense channels 226 but are omitted for clarity.

Returning to the five (5) portions (e.g., layers) of the sense resistor 200, the first metal interconnect 204 and/or the second metal interconnect 212 may be constructed with any type of metal, such as copper or aluminum. In some examples, the first metal interconnect 204 and/or the second metal interconnect 212 exhibit a temperature coefficient (TC) value in excess of +3000 ppm/C, but examples described herein are not limited thereto.

In some examples, the first resistive head 206 and/or the second resistive head 210 may be constructed with a polysilicon material (e.g., implanted polysilicon), in which the polysilicon material includes the addition of silicide (e.g., Cobalt silicide, Nickel silicide, Titanium silicide, etc.). As used herein, the process of adding and/or otherwise incorporating a silicide material is referred to herein as “silicidation.” In particular, the silicide is added and/or otherwise incorporated into the resistive heads in an effort to reduce a resistivity property, thereby reducing a contributory resistive effect of the sense resistor 200. Stated differently, the resistive body 208 is fabricated in a manner to achieve a target resistance and the other portions (e.g., layers) of the sense resistor 200 are portions that are not intended to affect and/or otherwise alter that target resistance value. Accordingly, silicidation lowers the resistivity properties of the resistive heads to facilitate relatively lower resistance contacts with metal interconnects.

In some examples, silicidation forms a silicide with a metal (e.g., Cobalt) followed by a thermal formation to create Cobalt silicide. In some examples, the silicide is added to the first resistive head 206 and/or the second resistive head 210 via one or more sputtering and/or annealing techniques. Although the incorporation of the silicide into the resistive heads reduce the resistivity of the polysilicon material, such silicide incorporation results in an increased temperature drift by increasing a TC value of those resistive heads (e.g., the first resistive head 206 and/or the second resistive head 210). In some examples, the first resistive head 206 and/or the second resistive head 210 exhibit approximate TC values in excess of −1500 ppm/C.

In some examples, the resistive body 208 may be constructed with the same polysilicon material as the resistive heads. One or more implant techniques are applied to the body layer 208 to establish the target resistance value (e.g., CMOS source or drain implants may be used, or dedicated masks may be used to set any value of sheet resistance needed). However, while the resistive heads described above include one or more silicide formations (constructed using a silicidation technique), the resistive body 208 is treated with a silicide blocking (SIBLK) material to prevent one or more effects caused by a subsequent silicidation technique that is performed on the adjacent resistive heads. In some examples, the resistive body 208 exhibits approximate TC values less than 100 ppm/C, which is substantially lower than TC values associated with the resistive heads and/or metal interconnects. In some examples a material void 222 is constructed into the resistor 200. In other examples an insulative material 222 resides in the resistor adjacent to the resistive head 206, metal interconnect 204 and/or the first sense terminal 252.

In operation, the sense resistor 200 eliminates and/or otherwise reduces erroneous measurements caused by metal interconnects and/or resistive heads. Also, the sense resistor 200 described herein reduces measurement errors caused by temperature fluctuations, particularly in view of temperature fluctuations that occur on materials that exhibit relatively high TC values. Examples described herein facilitate voltage measurements across the first sense terminal 252 and the second sense terminal 254, which bypass effects exhibited by metal and/or head polysilicon layers (e.g., the first metal interconnect 204 and the second metal interconnect 212).

Unlike primary current-carrying metal interconnects and/or terminals extending therefrom, the sense terminals are not primary current-carrying and facilitate conductive contact with a portion of the resistive body 208 with reduced or no exposure to resistive head materials. As such, the sense terminals exhibit a TC associated with the resistive body 208 of the sense resistor 200, which has a relatively low spread. In view of the reduced influence of relatively large TC value materials when making measurements with the sense terminals, ineffective and/or otherwise erroneous correction techniques are reduced or eliminated (e.g., post processing algorithms to adjust voltage values based on available temperature data).

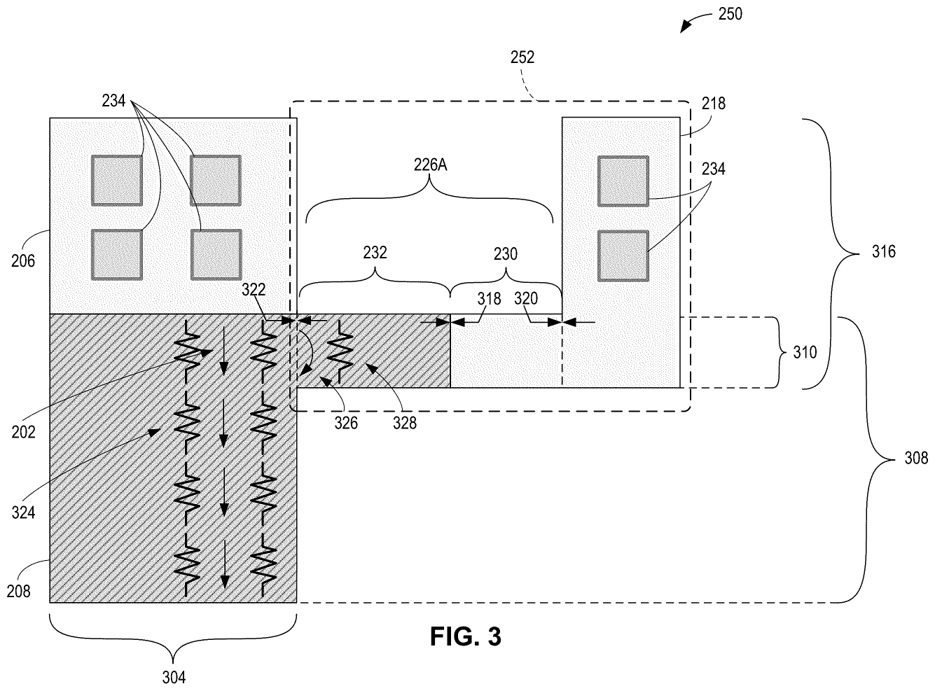

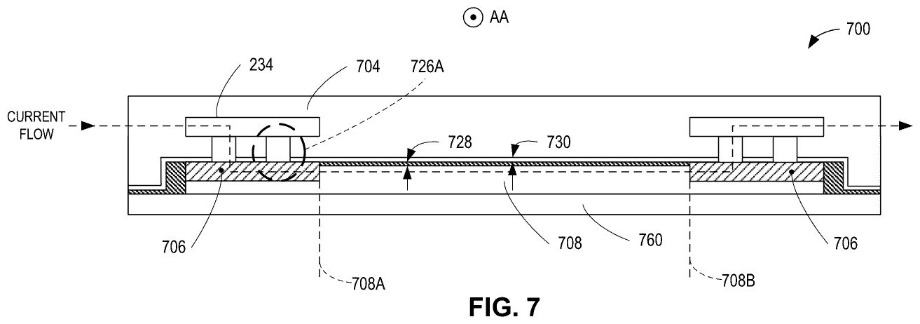

In the example of FIG. 2, a portion of the sense resistor 200 (see dashed circle 250) including the sense terminal 252 and its associated connection to the resistive body 208 is described in further detail in the example of FIG. 3. Additionally, a cross-sectional view of FIG. 2 is described below in connection with FIG. 7 from the point of view of marker AA along the primary current flow line 202.

In the example of FIG. 3, similar structure as described above in connection with FIG. 2 include the same reference numbers, where appropriate. The portion of the sense resistor 250 includes the sense terminal 252, the current flows 202, the first head layer 206, the resistor head contacts 234, the body layer 208, the first sense channel 226A, the first portion of the sense channel 230, and the second portion of the sense channel 232. In some examples, the second portion of the sense channel 232 is referred to as a body extension. As described above and in further detail below, an initial SIBLK process (including a corresponding silicide blocking material) is applied to the body layer 208 to block a subsequent silicide layer application process. In the example of FIG. 3, the silicide blocking material is represented with a diagonal crosshatch of the body layer 208 and the second portion of the sense channel 232.

In the example of FIG. 3, the body layer 208 includes a first portion 304 adjacent to the second portion of the sense channel 232, such that an end portion of the channel 226A is coupled to the body layer 208. In some examples, the first portion 304 and the second portion 232 are referred to as a first conductive structure. The first portion 304 includes a first dimension 308 in a first direction parallel to the current flows 202, and the second portion of the sense channel 232 includes a second dimension 310 in the first direction parallel to the current flows 202. In some examples, the first dimension 308 and the second dimension 310 are referred to as a thickness of the body layer 208 and the second portion 232, respectively. In the example of FIG. 3, the second dimension 310 is less than the first dimension 308.

In the example of FIG. 3, the first portion 304 also includes a third dimension 304 that is orthogonal to the first dimension 308. Also, the second portion of the sense channel 232 includes a fourth dimension 232 orthogonal to the second dimension 310, and the fourth dimension 232 extends beyond boundaries of the third dimension 304.

In the example of FIG. 3, the first sense terminal 252 is a portion of the second conductive structure 218. The first sense terminal 252 includes the first portion of the sense channel 230 having a fifth dimension 310 in the first direction parallel to the current flows 202. The first portion of the sense channel 230 is conductively connected to a sense terminal 252 having a sixth dimension 316 in the first direction parallel to the current flows 202. In some examples, the first sense terminal 252 includes the first portion of the sense channel 230 (e.g., sometimes referred to as a first section of the sense terminal 252) as well as a second portion of the sense channel 232 (e.g., sometimes referred to as a second section of the sense terminal 252). In some examples, the first sense terminal 252 is decoupled from the first head layer 206 (e.g., the first resistive head 206). In some examples, the second section of the sense terminal 232 is coupled between the first section of the sense terminal 230 and the resistor body 208.

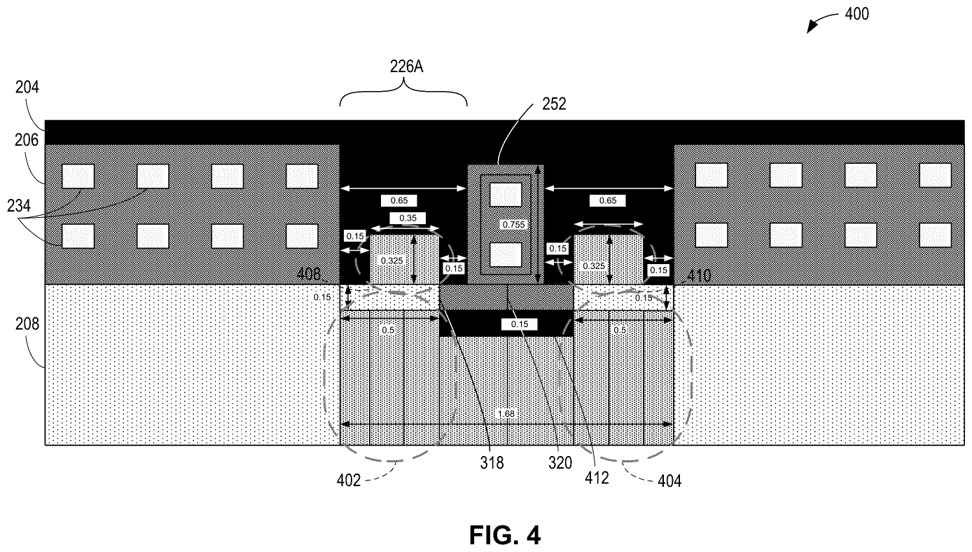

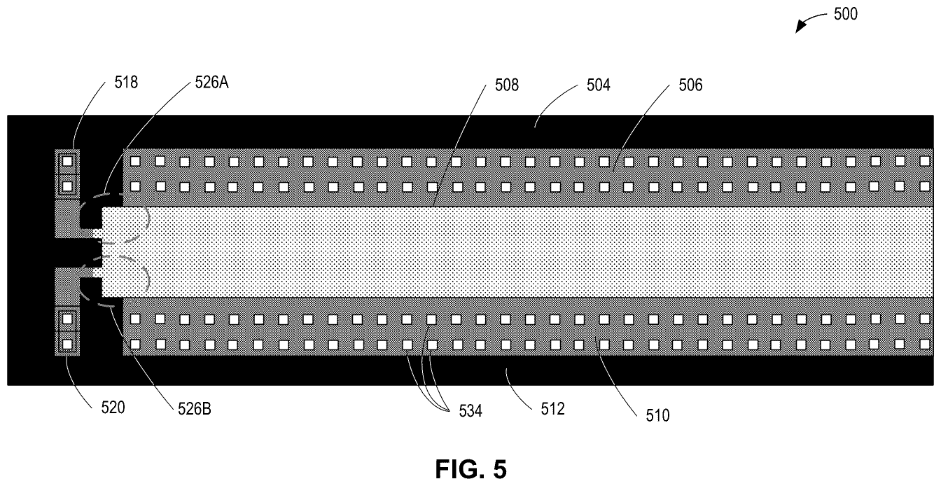

Also, in the example of FIGS. 2 and 3 (and FIG. 4), an end portion of the sense channels are coupled at or substantially near a boundary between the head layer 206 and the body layer 208. In another example (e.g., FIG. 5), an end portion of the sense channels are coupled away from a boundary between the head layer and the body layer. In another example (e.g., FIG. 5), an end portion of the sense channels are coupled to an end of the body layer.

In the example of FIG. 3, the fifth dimension 310 of the first portion of the sense channel 230 is equal to fourth dimension 232 of the second portion of the sense channel 232. Stated differently, the first portion of the sense channel 230 has a same thickness as the second portion of the sense channel 232, the boundary of which forms a sense interface 318. The sense interface 318 is a boundary of two dissimilar materials, one of which includes silicide (e.g., a silicide formation, Cobalt silicide, Nickel silicide, Titanium silicide, etc.) and the other of which includes a silicide block and/or is otherwise prevented from having a silicide additive. Accordingly, one side of the sense interface 318 exhibits material properties having a first resistivity and TC, and the other side of the sense interface 318 includes a second resistivity and TC. Also, the fourth dimension 232 of the second portion of the sense channel 232 is non-overlapping with the third dimension 304 of the first portion 304. As described in further detail below, this non-overlapping structure 232 is sometimes referred to as the base extension and exhibits particular electrical characteristics to improve resistor-based current measurements.

In the example of FIG. 3, the sense channel 226A includes a distal end 320 conductively connected to the sense terminal 252, and a proximal end 322 conductively connected to the first portion 304 of the body layer 208.

In operation, current flow 202 through the head layer 206 and the body layer 208 is subject to a particular resistance 324 that is a function of the body layer type (e.g., masking, doping, etc.) and the head layer 206. While the first sense terminal 252 does not function as a primary current path for the sense resistor 200, because the first sense channel 226A is a structure having conductive material, some current flow 202 (e.g., the primary current path) follows any path available to it. In the example of FIG. 3, a current bend path 326 occurs by virtue of a sense channel resistance 328. The magnitude of the current bend path 326 is inversely proportional to the sense channel resistance 328. However, because the second portion of the sense channel 232 includes the silicide block, the associated resistivity is relatively higher, thereby lowering the magnitude of the current bend path 326. Also, because the second portion of the sense channel 232 includes the silicide block, the associated TC is relatively lower, making the current bend path 326 values less affected by temperature variations and, as such, reduces erroneous measurements of the sense resistor 200 in the presence of temperature fluctuations.

For the sake of discussion, in the event the second portion of the sense channel 232 did not include the silicide block, the corresponding sense channel resistance 328 of the current bend path 326 would be relatively lower, thereby resulting in a relatively larger current bend path 326 magnitude. Also, in the event the second portion of the sense channel 232 did not include the silicide block, the corresponding TC would be relatively larger, thereby resulting in a voltage drop over the sense channel resistance 328 having a greater degree of erroneous variation as temperature changes.

FIG. 4 illustrates example dimensions of the sense resistor 200 and example structure to facilitate mask alignment and fabrication tolerance control. In the example of FIG. 4, a similar structure as described above in connection with FIGS. 2 and 3 includes the same reference numbers, where appropriate. In particular, the sense resistor 200 of FIG. 4 includes the first metal layer 204, the first head layer 206, the body layer 208, the sense terminal 252, the first portion of the sense channel 230, the second portion of the sense channel 232, the first sense channel 226A (e.g., the combined first portion of the sense channel 230 and the second portion of the sense channel 232), the resistor head contacts 234, and the sense interface 318.

The example of FIG. 4 includes a first mask alignment structure 402, a second mask alignment structure 404, a third mask alignment structure 406, a fourth mask alignment structure 408, and a fifth mask alignment structure 410. The first mask alignment structure 402, the second mask alignment structure 404, the fourth mask alignment structure 408 and the fifth mask alignment structure 410 facilitate silicide blocking of underlying polysilicon layer in a vertical direction to facilitate the adjacent and relatively high current carrying resistors of the body 208. The unsilicided (e.g., by virtue of SIBLK) body 208 and channel extension (the second portion of the sense channel 232) has approximately 10× higher sheet resistance. The above described mask alignment structures may be different types of silicide block materials, such as Tetraethyl orthosilicate (TEOS) formed and/or otherwise created by a chemical vapor deposition (CVD) process. The example third mask alignment structure 406 facilitates silicide blocking spacing for the sense terminal 252 to allow polysilicon under such contacts to be silicided. The example of FIG. 4 also includes an alignment tolerance spacing 412 to facilitate resistor head spacing with respect to the sense terminal 252. While example dimensions in micrometers are illustrated in FIG. 4, examples described herein are not limited thereto and depends on particular design choices.

FIG. 5 illustrates an example alternative sense resistor 500, that may be implemented as the sense resistor 108, in which sense terminals are structured on a side or end of a resistor body. In the example of FIG. 5, a similar structure as described above in connection with FIGS. 2, 3 and 4 includes similar reference numbers that are preceded with the number “5” (e.g., “5XX”). For instance, a body layer of FIGS. 2, 3 and 4 is labeled as 208, but is labeled as 508 in the example of FIG. 5. The sense resistor 500 of FIG. 5 includes a first metal layer 504, a second metal layer 512, a first head layer 506, a second head layer 510, head contacts 534, a first sense channel 526A, a second sense channel 526B, a first sense terminal 518, and a second sense terminal 520.

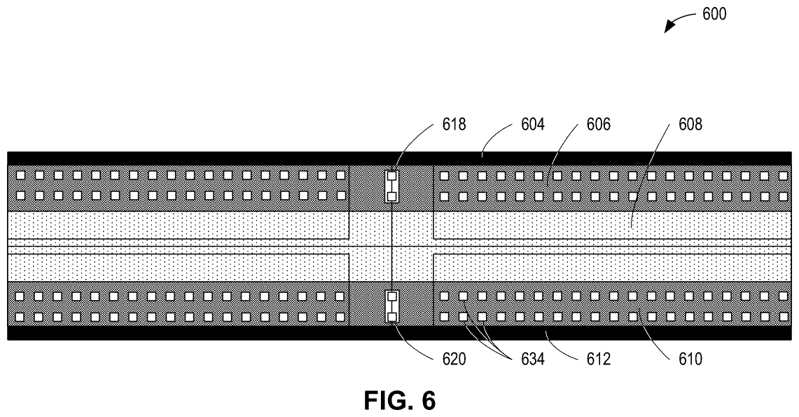

FIG. 6 illustrates an example alternative sense resistor 600, that may be implemented as the sense resistor 108, in which metal routing resistance contributions are removed by omitting a body extension of poly. In the example of FIG. 6, a similar structure as described above in connection with FIGS. 2, 3, 4 and 5 includes similar reference numbers that are preceded with the number “6” (e.g., “6XX). For instance, a body layer of FIGS. 2, 3 and 4 is labeled as 208, but is labeled as 608 in the example of FIG. 6. The sense resistor 600 of FIG. 6 includes a first metal layer 604, a second metal layer 612, a first head layer 606, a second head layer 610, head contacts 634, a first sense terminal 618, and a second sense terminal 620.

FIG. 7 illustrates an example sense resistor 700 as a cross-sectional view. In the example of FIG. 7, a similar structure as described above in connection with FIGS. 2, 3 and 4 includes similar reference numbers that are preceded with the number “7” (e.g., “7XX”). The sense resistor 700 of FIG. 7 includes a body layer 708 formed between head layers 706, all of which are built upon shallow trench isolation (STI) 760. In some examples, the body layer 708 is formed via LOCal Oxidation of Silicon (LOCOS). The body layer 708 may be a high sheet resistor implanted with Boron (e.g., Boron implanted polysilicon) to achieve any sheet resistance value of interest. The example of FIG. 7 includes the head layers 706 with silicide in which the silicided head layers form the boundaries of the body layer 708 (see a first head layer boundary 708A and a second head layer boundary 708B). The example sense resistor 700 of FIG. 7 also includes a sidewall area 706 having a silicide block (SIBLK), and an oxide metal layer 704 (e.g., a metal dielectric or deposited oxide). The example sense resistor 700 of FIG. 7 also includes metal contacts 718 (e.g., Aluminum, Copper, etc.).

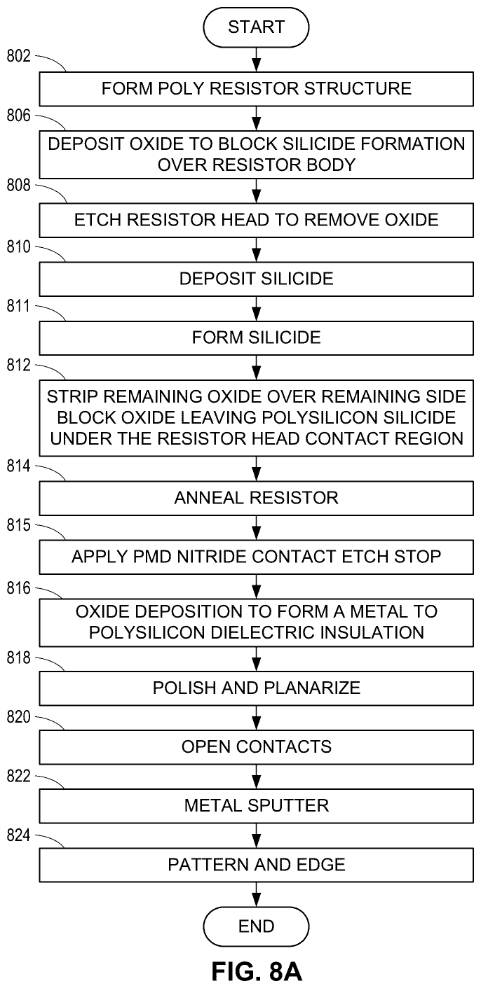

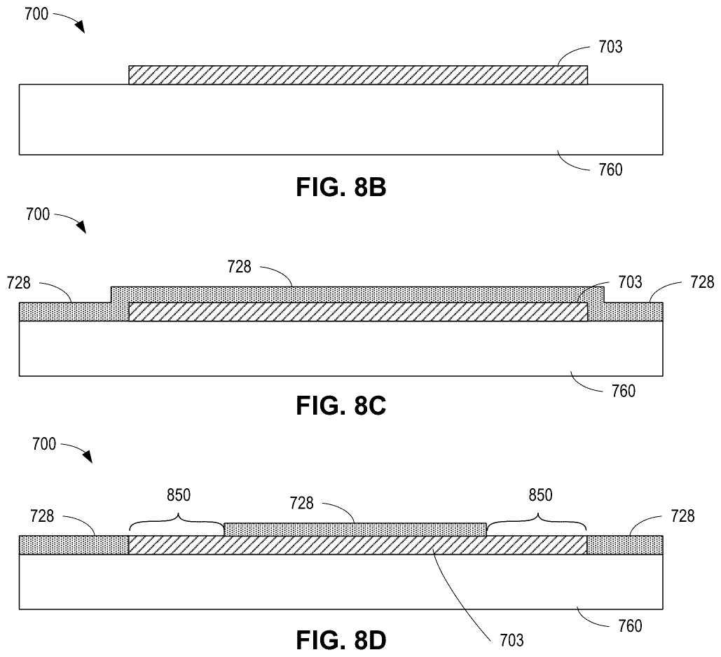

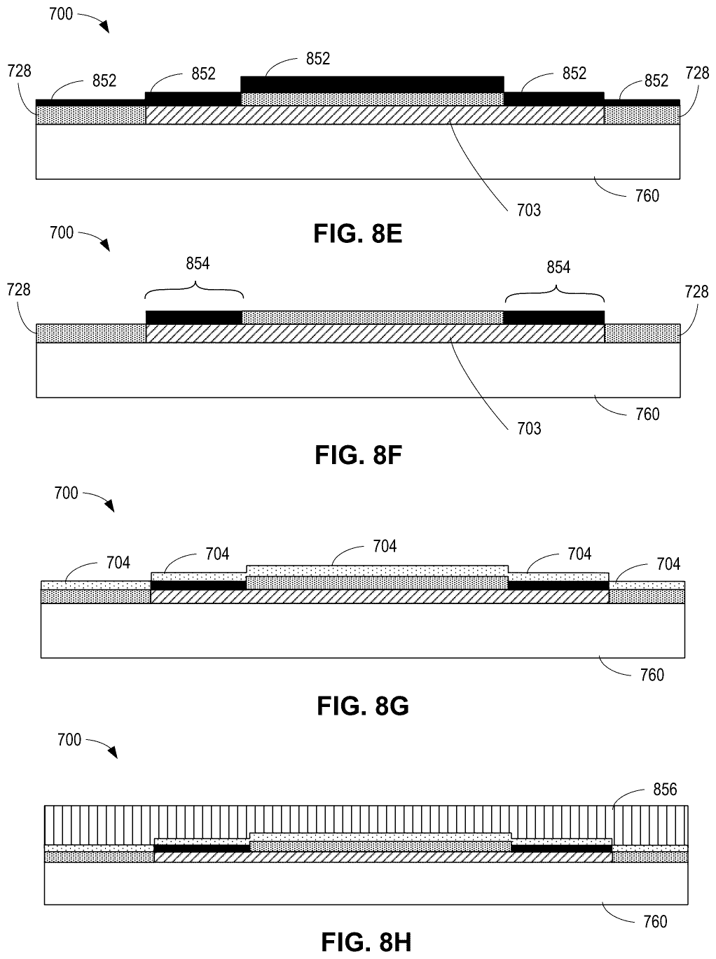

The example sense resistor 700 of FIG. 7 includes a silicide block layer 728 that is deposited over the entirety of the resistor wafer, in which one or more portions are later opened with block patterns to cause silicide to react with polysilicon and/or crystalline silica. As described above, particular formations of sense channels facilitate improvements to thermal stability of the sense resistor 700. The example sense resistor 700 includes contacts 726 between the metal contacts 718 and the silicided head layer 706. The example sense resistor 700 includes a poly to metal dielectric (PMD) Nitride 730 to operate as a contact etch stop layer. An example formation of the sense resistor 700 of FIG. 7 is described below in connection with a flowchart of FIG. 8A and respective fabrication stage illustrations of FIGS. 8B through 8H.

FIG. 8A is a flowchart 800 of an example manner to facilitate silicide application (silicidation) and blocking for a sense resistor. A resistor is initially formed with a doped poly high sheet resistor body and head (block 802). In particular, FIG. 8B illustrates the resistor 700 corresponding to block 802, which includes the shallow trench isolation 760 and an etched pattern of polysilicon 703 with no oxide above it. An oxide deposition is applied to block silicide formation (SIBLK) over the resistor body (block 806), which is described above in the example of FIG. 7 as the silicide block layer 728, and is also shown in the example of FIG. 8C. In some examples, the oxide deposition is 300 angstroms thick, but other dimensions are possible. After the oxide deposition (block 806), silicide block resist is applied to the resistor body 708 in a manner consistent with structures illustrated in FIGS. 2-5 to facilitate formation of the second portion of the sense channel 232 so that the silicide block oxide is protected during one or more etching techniques.

In particular, the resistor head is etched to remove the oxide (block 808) to facilitate formation of the first portion of the sense channel 230, which may be performed with plasma etching techniques, as shown in the example of FIG. 8D. In particular, the example of FIG. 8D includes oxide voids 850 caused by the etching corresponding to block 808 of FIG. 8A. As shown in the example of FIG. 8E, a metal sputter technique is performed to deposit Cobalt 852 so that silicide formation occurs over the resistor head layer(s) 706, but not over the resistor body 708 (which is protected by the silicide block oxide 728) (block 810). As shown in the example of FIG. 8F, the silicide is formed (block 811) over portions that do not include the silicide block oxide 728 (e.g., the head layers 706, see voids 854).

In some examples, forming the silicide is referred to as “silicide formation” or a “thermal anneal.” Forming the silicide makes it immune to one or more silicide strip techniques to strip remaining silicide over remaining side block oxide leaving polysilicon silicide under the resistor head contact region (block 812). Stated differently, the silicide is removed from over the silicide block oxide. A silicide anneal technique causes silicide formation where the silicide remains over the resistor head (block 814), which facilitates achieving a target molecular composition for the silicide. As shown in the example of FIG. 8G, one or more additional oxide deposition techniques are applied over the resistor to form a metal-to-polysilicon dielectric insulation 704 (block 816). As shown in the example of FIG. 8H, chemical mechanical polishing (CMP) is performed to planarize pre-metal dielectric (PMD) oxide(s) 856 (block 818). Metal sputtering facilitates formation of metal layers to the wafer to form contacts (block 822) (see 726A) between metal contacts and the head 706, and pattern/edge techniques facilitate contact formation to form head contacts 234 (block 824). Contact pattern techniques are applied to open the contacts in the PMD oxide(s) down to MOAT and the poly resistor head (block 820), as shown in the example of FIG. 7.

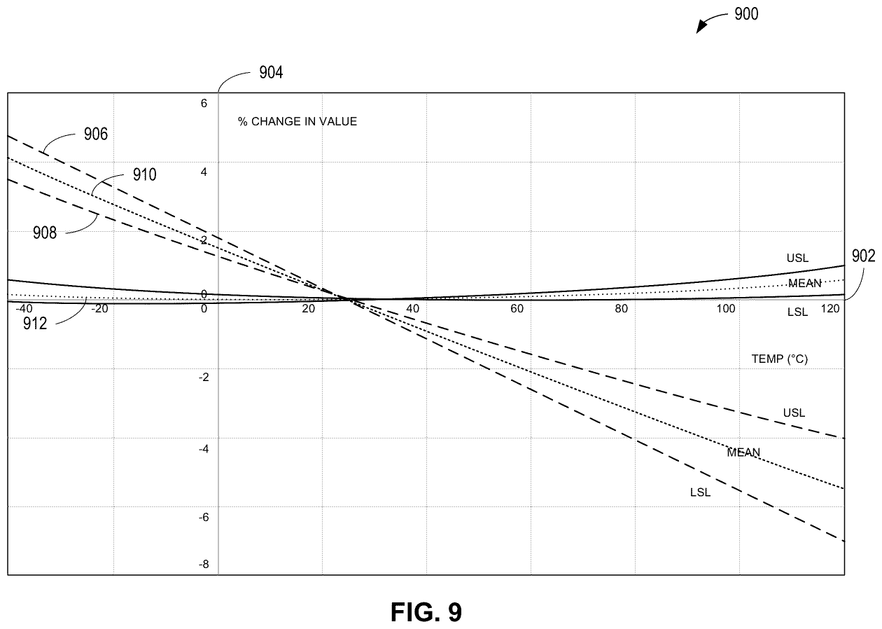

FIG. 9 is a temperature versus percent change in value graph 900 to illustrate sense resistor performance improvements realized by examples described herein. In the example of FIG. 9, an x-axis includes temperature in degrees C. 902 and a y-axis includes percent change in value 904. A non-sense-resistor curve includes mean performance values 906 within an upper specification limit (USL) 908 and a lower specification limit (LSL) 910. Conversely, a sense resistor curve consistent with teachings described herein include mean performance values 912. The non-sense-resistor exhibits approximately +/−1.5% spread when considered up to 120 degrees C. However, sense resistor examples described herein exhibit approximately +/−0.4% spread when considered up to 120 degrees C. Accordingly, sense resistor examples described herein facilitate over a three-times reduction in error spread and over a five-times reduction in mean error across such temperature fluctuations.

Descriptors “first,” “second,” “third,” etc. are used herein when identifying multiple elements or components which may be referred to separately. Unless otherwise specified or articulated based on their context of use, such descriptors do not impute any meaning of priority, physical order, or arrangement in a list, or ordering in time but are merely used as labels for referring to multiple elements or components separately for ease of understanding the described examples. In some examples, the descriptor “first” may be used to refer to an element in the detailed description, while the same element may be referred to in a claim with a different descriptor such as “second” or “third.” In such instances, it should be interpreted that such descriptors are used merely for ease of referencing multiple elements or components.

In the description and in the claims, the terms “including” and “having” and variants thereof are intended to be inclusive in a manner similar to the term “comprising” unless otherwise noted. Unless otherwise stated, “about,” “approximately,” or “substantially” preceding a value means+/−10 percent of the stated value. In another example, “about,” “approximately,” or “substantially” preceding a value means+/−5 percent of the stated value. In another example, “about,” “approximately,” or “substantially” preceding a value means+/−1 percent of the stated value.

The term “couple”, “coupled”, “couples”, and variants thereof, as used herein, may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A. Moreover, the terms “couple”, “coupled”, “couples”, or variants thereof, includes an indirect or direct electrical or mechanical connection.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

Although not all separately labeled in the figures, components or elements of systems and circuits illustrated therein have one or more conductors or terminus that allow signals into and/or out of the components or elements. The conductors or terminus (or parts thereof) may be referred to herein as pins, pads, terminals (including input terminals, output terminals, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically and/or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on a particular circuit or system topology, there may be more or fewer terminals and nodes. However, in some instances, “terminal”, “node”, “interconnect”, “pad”, and “pin” may be used interchangeably.

From the foregoing, it is appreciated that example apparatus and methods have been described that improve an ability to acquire current measurements in environments that experience temperature fluctuations. In some examples described herein, problematic and/or otherwise negative effects caused by current bending are reduced by, in part, extending a body material into the sense channel, thereby reducing a current bending quantity that would otherwise contribute to erroneous measurements. Also, examples described herein facilitate a sense channel having a temperature coefficient property that is relatively lower to reduce errors when temperature fluctuations occur. Described apparatus and methods are accordingly directed to one or more improvement(s) in the operation of a machine, such as an electronic device that employs one or more sense resistors described herein.

The following claims are hereby incorporated into this Detailed Description by this reference. Although certain example systems, apparatus, articles of manufacture, and methods have been described herein, the scope of coverage of this patent is not limited thereto. On the contrary, this patent covers all systems, apparatus, articles of manufacture, and methods fairly falling within the scope of the claims of this patent.

Modifications are possible in the described example, and other examples are possible, within the scope of the claims.

What is claimed is:

1. A semiconductor device comprising:
a resistor head comprising a first material;
a resistor body coupled to the resistor head and comprising a second material having a higher resistivity than the first material; and
a sense terminal having a first section and a second section and being decoupled from the resistor head, in which the second section of the sense terminal is coupled between the first section of the sense terminal and the resistor body, with an end portion of the second section of the sense terminal coupled to the resistor body.

2. The semiconductor device of claim 1, wherein the first section of the sense terminal comprises a third material, and at least the end portion of the second section of the sense terminal comprises the second material.

3. The semiconductor device of claim 2, wherein the second section of the sense terminal has another end portion coupled to the first section of the sense terminal, and the another end portion comprises the third material.

4. The semiconductor device of claim 2, wherein the third material is the same as the first material.

5. The semiconductor device of claim 2, wherein the first material and the third material comprises polysilicon having a silicide formation, and the second material comprises polysilicon without a silicide formation.

6. The semiconductor device of claim 1, wherein the end portion of the second section of the sense terminal is coupled at or substantially near a boundary between the resistor head and the resistor body.

7. The semiconductor device of claim 1, wherein the end portion of the second section of the sense terminal is coupled away from a boundary between the resistor head and the resistor body.

8. The semiconductor device of claim 1, wherein the end portion of the second section of the sense terminal is coupled to an end of the resistor body.

9. A semiconductor device comprising:
a resistor head comprising a first material;
a resistor body coupled to the resistor head and comprising a second material having a higher resistivity than the first material; and
a sense terminal having a first section and a second section, in which the second section of the sense terminal is coupled between the first section of the sense terminal and the resistor body, with an end portion of the second section of the sense terminal coupled to the resistor body, and in which the end portion of the second section of the sense terminal comprises a third material having a higher resistivity than the first material.

10. The semiconductor device of claim 9, wherein the sense terminal is decoupled from the resistor head.

11. The semiconductor device of claim 9, wherein the second material is the same as the third material.

12. An integrated circuit comprising:
a resistor including:
a first resistor head comprising a first material;
a resistor body coupled to the first resistor head at a first side of the resistor body, the resistor body comprising a second material having a higher resistivity than the first material;
a second resistor head coupled to a second side of the resistor body;
a sense terminal having a first section and a second section and being decoupled from the resistor head, in which the second section of the sense terminal is coupled between the first section of the sense terminal and the resistor body, with an end portion of the second section of the sense terminal coupled to the resistor body, wherein the first section of the sense terminal comprises a third material, and at least the end portion of the second section of the sense terminal comprises the second material.

13. The integrated circuit of claim 12, further comprising an amplifier output stage coupled to the first resistor head.

14. The integrated circuit of claim 13, wherein the second resistor head is adapted to be coupled to an audio device.

15. The integrated circuit of claim 12, further comprising voltage sense circuitry coupled to the sense terminal.
